(19) United States
(12) Patent Application Publication
(10) Pub. No.: US 2024/0239201 A1
(43) Pub. Date: Jul. 18, 2024

(54) ELECTRONIC PRE-CHARGE RELAY DEVICE AND DRIVING METHOD THEREOF

(71) Applicant: Elevation microsystems, Inc., Wilmington, DE (US)

(72) Inventors: Kyung Min KIM, Seongnam-si (KR); Ick Chan JEONG, Hwaseong-si (KR); Wan Ki HONG, Bucheon-si (KR)

(21) Appl. No.: 18/180,771

(22) Filed: Mar. 8, 2023

(30) Foreign Application Priority Data
Jan. 13, 2023 (KR) 10-2023-0005412

(51) Int. Cl. B60L 3/00; H02M 1/08; H02M 3/335

(52) U.S. Cl. CPC B60L 3/0046; H02M 1/082; H02M 3/33569; B60L 2210/30; B60L 2240/547

(57) ABSTRACT

An electronic pre-charge relay device according to an embodiment of the present invention comprises: a control signal input unit for inputting a control signal for turning on and off; an AC conversion unit for converting the control signal into an AC signal; an insulating transform unit for boosting the converted AC control signal to a predetermined voltage level; a rectifying and smoothing unit for converting the boosted AC control signal into a DC input signal; a power semiconductor switch having a gate used to turn on and off to supply electrical energy to a load in relation to the control signal; and a gate signal generation unit for generating at least one gate signal suitable for the power semiconductor switch by using the converted DC input signal.

### CROSS REFERENCE TO RELATED APPLICATION

This application claims priority under 35 U.S.C § 119 to Korean Patent Application No. 10-2023-0005412 filed in the Korean Intellectual Property Office on Jan. 13, 2023, the entire contents of which is hereby incorporated by reference.

### FIELD OF THE INVENTION

The present invention relates to an electronic pre-charge relay device and a driving method thereof. More specifically, the present invention relates to an electronic pre-charge relay device for a inverter to which high electrical energy is applied in a hybrid vehicle or an electric vehicle, and a driving method thereof.

### BACKGROUND OF THE RELATED ART

Electric vehicles are rapidly replacing vehicles of an internal combustion engine recently owing to their advantages in environment, cost, and performance. The electric vehicles are driven by converting electrical energy stored in a battery pack into kinetic energy. In this case, it is inevitable that a high current is applied from a high voltage source to a inverter.

FIG. 1 is a schematic view showing the function of a pre-charge relay in driving an electric vehicle.

In order to convert electrical energy into kinetic energy, an electric vehicle 1 may include a battery pack 20, a pre-charge relay 10, an inverter 30, and a driving motor 40.

The battery pack 20 is configured of a plurality of rechargeable batteries and operates as a DC voltage power supply capable of supplying a high DC voltage to the inverter 30.

The inverter 30 converts the high DC voltage applied from the battery pack 10 into a high AC voltage and provides the converted high AC voltage to the driving motor 40.

The driving motor 40 accelerates or decelerates the driving unit of the electric vehicle using the AC voltage provided by the inverter 30.

Meanwhile, when the high voltage applied from the battery pack 20 is applied to the inverter 30, an in-rush current in which an initial current value instantaneously soars may be induced in the inverter 30 that corresponds to the load side. Such an in-rush current is generated as an instantaneous high voltage is applied to an uncharged load side capacitor, and a high current unintentionally flows to the load side when the main switch is turned on.

The pre-charge relay 10 is used to prevent damage to the load, the main switch, and the battery caused by the in-rush current.

FIG. 2 is a circuit diagram for explaining the operation of a pre-charge relay device.

The pre-charge relay 10 may perform pre-charge as a relay switch 11 and a resistor 12 are connected to the main switches SW_M1 and SW_M2 in parallel. As the resistor 12 connected to the relay switch 11 in series limits incoming current and the relay switch 11 charges the capacitor included on the load side (inverter 30) before the main switch is turned on, voltage difference between the load and the battery pack 20 is reduced. Then, when the main switch is turned on, the battery pack 20 may supply electrical energy to the load 30 while minimizing the in-rush current.

Meanwhile, in the prior art, a mechanical relay device is used as the relay switch 11 for a high voltage source. The mechanical relay device includes a spring and a movable armature, and two contacts are connected to or separated from each other by a control signal and an electromagnetic force.

Although such a mechanical relay device is suitable for switching high voltage, there are many problems when it is used in an electric vehicle. Specifically, mechanically implemented contacts are vulnerable to vibration, and thus contact defects may occur. In addition, wear of mechanical structures and changes in the characteristics may also occur. In addition, an arc generated by an instantaneous voltage difference between the two contacts causes a limit in the lifespan of the relay due to the damage to the contacts.

Particularly, a back electromotive force (emf) generated in a coil to generate an electromagnetic field also causes damage to the controller of an electric vehicle that requires precise electronic control. In addition, a large-capacity resistor should also be used as the resistor 12 connected in series to withstand high heat and current, and there is a problem in that the overall pre-charge time increases.

Meanwhile, together with recent advancement in electric vehicles, power semiconductors are spotlighted as a key component of the electric vehicles. Such a power semiconductor provides high durability while being operable in an environment using high voltage and current.

Transistors of the power semiconductor include silicon-based insulated gate bipolar transistors (IGBTs), and there also exist silicon carbide (SiC) or gallium nitride (GaN) transistors using a wide bandgap (WBG) material.

Therefore, in order to solve the problems of the prior art, it needs to provide an electronic pre-charge relay device suitable for the power semiconductors.

### SUMMARY OF THE INVENTION

Therefore, the present invention has been made in view of the above problems, and it is an object of the present invention to provide an electronic relay device for preventing malfunction, mechanical wear, and defects generated by vibration, and a driving method thereof.

In addition, another object of the present invention is to provide a pre-charge relay device optimized for the characteristics of power semiconductor transistors, and a driving method thereof.

The technical problems to be solved by the present invention are not limited to the technical problems mentioned above, and unmentioned other technical problems can be clearly understood by those of skilled in the art from the following description.

To accomplish the above objects, according to one aspect of the present invention, there is provided an electronic pre-charge relay device comprising: a control signal input unit for inputting a control signal for turning on and off; an AC conversion unit for converting the control signal into an AC signal; an insulating transform unit for boosting the converted AC control signal to a predetermined voltage level; a rectifying and smoothing unit for converting the boosted AC control signal into a DC input signal; a power semiconductor switch having a gate used to turn on and off to supply electrical energy to a load in relation to the control signal; and a gate signal generation unit for generating at least one gate signal suitable for the power semiconductor switch by using the converted DC input signal.

Here, the gate signal generation unit may include a chopper signal generation unit, and the chopper signal generation unit may generate a pulse that gradually increases on-duty time as a gate signal on the basis of the DC input signal.

Here, the chopper signal generation unit may include: a pulse generator for generating a pulse corresponding to the DC input signal; and a duty ratio controller for controlling to gradually increase on-duty timeon-duty time of the generated pulse.

In addition, the gate signal generation unit may further include an under voltage protection unit that determines a voltage of the DC input signal as a voltage of the gate signal only when the voltage of the DC input signal is higher than a predetermined voltage level.

The power semiconductor switch may include a first power semiconductor switch and a second power semiconductor switch having different minimum gate-source voltages, and the under voltage protection unit may be configured to operate when a gate signal for the first power semiconductor switch having a relatively higher minimum gate-source voltage is generated.

In addition, the gate signal generation unit may further include a first negative voltage generation unit for generating a gate signal of a negative voltage level determined based on a Zener voltage of at least one Zener diode connected between a gate and a source of the power semiconductor switch using the voltage charged in the load when the control signal is turned off.

The power semiconductor switch may include a first power semiconductor switch and a second power semiconductor switch having different minimum gate-source voltages, and the first negative voltage generation unit may be configured to operate when a gate signal for the second power semiconductor switch having a relatively lower minimum gate-source voltage is generated.

In addition, the chopper signal generation unit may further include a second negative voltage generation unit for generating a gate signal of a negative voltage level at the gate of the power semiconductor switch when the control signal is turned off, wherein the power semiconductor switch may include a first power semiconductor switch and a second power semiconductor switch having different minimum gate-source voltages, and the second negative voltage generation unit may be configured to operate when a gate signal for the second power semiconductor switch having a relatively lower minimum gate-source voltage is generated.

Here, the second negative voltage may be provided using a tap having a potential lower than a reference potential, among a plurality of taps on the secondary side of the insulating transform unit.

According to another embodiment of the present invention, there is provided a method of driving an electronic pre-charge relay, the method comprising the steps of: converting a control signal that is input to drive the electronic pre-charge relay into an AC signal, and boosting the AC signal to a predetermined voltage level; converting the converted and boosted AC signal into a DC signal by rectifying and smoothing the AC signal; generating a gate signal capable of driving a power semiconductor switch using the converted DC signal; and performing pre-charge by driving the power semiconductor switch using the generated gate signal, wherein the generated gate signal includes a chopper signal having a duty ratio that varies over time.

Here, the chopper signal may be a pulse that gradually increases on-duty time over time.

In addition, the power semiconductor switch may include a first power semiconductor switch and a second power semiconductor switch having different minimum gate-source voltages, and the step of generating a gate signal may include a step of determining that an under voltage protection is required when a gate signal for the first power semiconductor switch having a relatively higher minimum gate-source voltage is generated.

In addition, the step of generating a gate signal may further include a step of determining whether supply of a negative voltage for generating a gate signal of a negative voltage level to a gate of the power semiconductor switch is required when the control signal is turned off, and a step of determining that supply of the negative voltage for the second power semiconductor switch having a relatively lower minimum gate-source voltage is required.

Here, the negative voltage may have a voltage level determined based on a Zener voltage of at least one Zener diode connected between a gate and a source of the power semiconductor switch using a voltage charged in a load when the control signal is turned off.

In addition, the negative voltage may be provided using a tap having a potential lower than a reference potential, among a plurality of taps on the secondary side of the insulating transform unit used when the boosting is performed.

### BRIEF DESCRIPTION OF THE DRAWINGS

FIG. 1 is a schematic view showing the function of a pre-charge relay in driving an electric vehicle.

FIG. 2 is a circuit diagram for explaining the operation of a pre-charge relay device.

FIG. 3 is a block diagram showing the configuration of a pre-charge relay device according to an embodiment of the present invention.

FIG. 4 is a view showing a circuit for generating an input signal IN2 of a gate signal generation unit according to an embodiment of the present invention.

FIG. 5 is a view showing the configuration of a gate signal generation unit according to an embodiment of the present invention.

FIG. 6 is a view showing the circuit of an under voltage protection unit 161 according to an embodiment of the present invention.

FIG. 7 is a view showing the circuit of a first negative voltage generation unit 162 according to an embodiment of the present invention.

FIG. 8 is a view showing the configuration of a chopper signal generation unit 163 according to an embodiment of the present invention.

FIG. 9 is a view showing a second negative voltage generation unit according to an embodiment of the present invention.

FIG. 10 is a flowchart illustrating a method of driving a pre-charge relay according to an embodiment of the present invention.

FIG. 11 is a flowchart specifically illustrating a step of generating a gate signal according to an embodiment of the present invention.

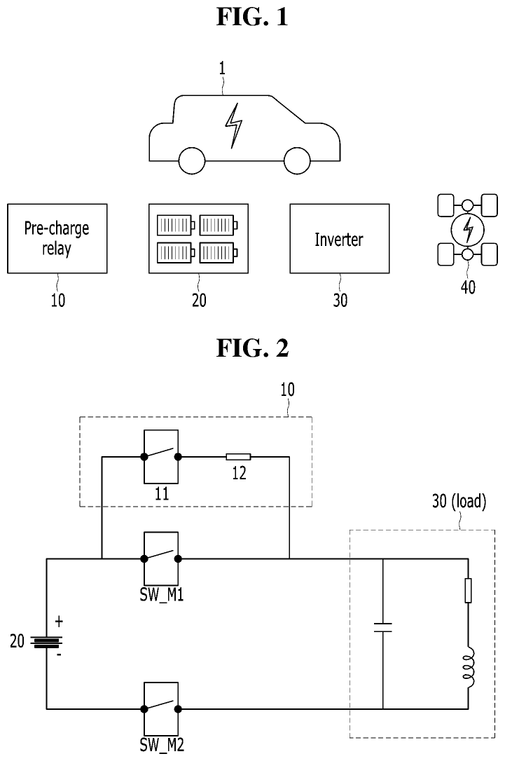

### DETAILED DESCRIPTION OF THE PREFERRED EMBODIMENT

Hereinafter, the present invention will be described with reference to the accompanying drawings. However, the present invention may be implemented in several different forms, and thus is not limited to the embodiments described herein. In addition, in order to clearly explain the present invention in the drawings, parts unrelated to the description are omitted, and similar reference numerals are attached to similar parts throughout the specification.

Throughout the specification, when a part is “linked (connected, contacted, coupled)” to another part, it includes the cases of being “indirectly connected” with intervention of another member therebetween, as well as the cases of being “directly connected”. In addition, when a part “includes” a certain component, this means that other components may be further provided, rather than excluding other components, unless clearly stated otherwise.

The terms used in this specification are used only to describe specific embodiments, and are not intended to limit the present invention. Singular expressions include plural expressions unless the context clearly dictates otherwise. It should be understood that in this specification, terms such as “comprise” or “have” are intended to specify existence of a feature, number, step, operation, component, part, or a combination thereof described in the specification, not to preclude the possibility of existence or addition of one or more other features, numbers, steps, operations, components, parts, or combinations thereof.

Hereinafter, embodiments of the present invention will be described in detail with reference to the accompanying drawings.

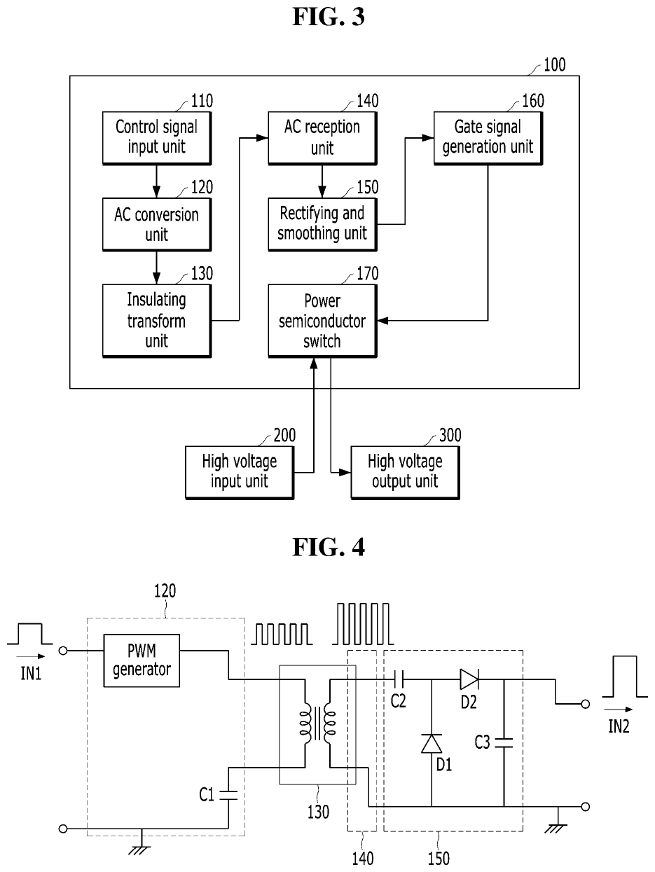

FIG. 3 is a block diagram showing the configuration of a pre-charge relay device according to an embodiment of the present invention.

A pre-charge relay device 100 according to an embodiment of the present invention includes a control signal input unit 110, an AC conversion unit 120, an insulating transform unit 130, an AC reception unit 140, a rectifying and smoothing unit 150, a gate signal generation unit 160, and a power semiconductor switch 170.

The control signal input unit 110 inputs a control signal for turning on or off a pre-charge relay. The control signal may be a single pulse or an input signal having a potential of a specific level.

The AC conversion unit 120 converts a control signal corresponding to turn-on into an AC signal in response to input of the control signal. The converted AC control signal may include a pulse signal generated by a pulse generator.

The converted AC control signal is input into the primary side of the insulating transform unit 130 and transformed to a potential of a level suitable for the gate signal of the power semiconductor toward the insulated secondary side.

The transformed AC signal is received by the AC reception unit 140 and converted into a DC signal by the rectifying and smoothing unit 150.

The converted DC signal is input into the gate signal generation unit 160 as an input signal and processed to be suitable for the gate signal of the power semiconductor. The gate signal generated by the gate signal generation unit 160 may include a negative signal, as well as a positive signal, and may include a chopper signal having a duty ratio that varies over time. The configuration and operation of the gate signal generation unit 160 will be described below in detail.

The gate signal generated by the gate signal generation unit 160 is applied to the gate of the power semiconductor switch 170 and controls on/off of the switch. The power semiconductor switch 170 includes at least one among an IGBT and a SiC or GaN transistor that uses a wide bandgap material.

Electrical energy supplied from a high voltage input unit 200 is supplied to a high voltage output unit 300 according to on/off of the power semiconductor switch 170. The high voltage input unit 200 may include a battery pack of the electric vehicle, and the high voltage output unit 300 may be a driving inverter of the electric vehicle or a certain circuit that operates as a load. That is, the high voltage output unit 300 may be regarded as a load to which the high voltage is applied in an embodiment of the present invention.

FIG. 4 is a view showing a circuit for generating an input signal of a gate signal generation unit according to an embodiment of the present invention.

The control signal IN1 is input into the AC conversion unit 120 and generates a corresponding pulse. The AC conversion unit may include a pulse width modulation (PWM) generator and a capacitor C1. The PWM generator outputs a PWM pulse, which is set to a time constant determined by the capacitor C1, to one end of the insulating transform unit 130.

The insulating transform unit 130 boosts the PWM pulse to a pulse signal of a higher voltage level and applies the pulse signal to both ends of the AC reception unit 140. At this point, since both ends of the insulating transform unit 130 are insulated, electromagnetic interference generated at the output terminal does not affect the controller.

Meanwhile, the duty of the PWM pulse is preferably set such that the values obtained by multiplying positive and negative voltage levels by a time are equal to each other in order to prevent saturation of the magnetic core of the insulating transform unit 130.

The rectifying and smoothing unit 150 couples the boosted PWM pulse signal through a capacitor C2 and clamps the signal through a diode D1. Then, a rectified and smoothed DC input signal IN2 is generated and output by a diode D2 and a capacitor C6.

In an embodiment of the present invention, the DC input signal IN2 is input into the gate signal generation unit 160, and the gate signal generation unit 160 receives the input signal IN2 and generates an optimum gate signal by performing a predetermined process.

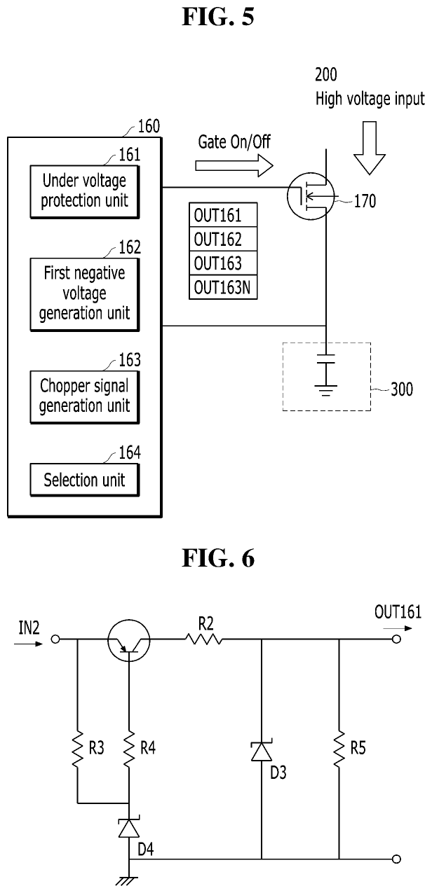

FIG. 5 is a view showing the configuration of a gate signal generation unit according to an embodiment of the present invention.

The gate signal generation unit 160 may include an under voltage protection unit 161, a first negative voltage generation unit 162, a chopper signal generation unit 163, and a selection unit 164.

The gate signal generation unit 160 generates a gate signal OUT161 processed for under voltage protection, a first negative voltage gate signal OUT162, a chopper-controlled gate signal OUT163, and a second negative voltage gate signal OUT163N, and provides the signals as a gate signal of the power semiconductor switch 170.

Here, the selection unit 164 may simultaneously or sequentially select and provide one among OUT161, OUT162, OUT163, and PIT163N or a combination thereof as a gate signal suitable for the power semiconductor switch 170, according to a predetermined setting or under the control of an operator.

FIG. 6 is a view showing the circuit of an under voltage protection unit 161 according to an embodiment of the present invention.

The under voltage protection unit 161 is configured to apply a gate voltage from the moment when the resulting voltage of the rectified and smoothed DC input signal IN2 exceeds a specific voltage (e.g., 12V) using the resistors R3 and R4 connected to the transistor and the Zener diode D4.

The under voltage protection unit 161 may also control the magnitude of the voltage of the gate signal of OUT161 by adjusting the Zener voltage of the Zener diode D3.

The under voltage protection unit 161 may be usefully used to generate a gate signal that safely operates the IGBT power semiconductor switch, rather than a SiC power semiconductor, within a Safe Operation Area (SOA) and quickly block the gate when an OFF control signal is received.

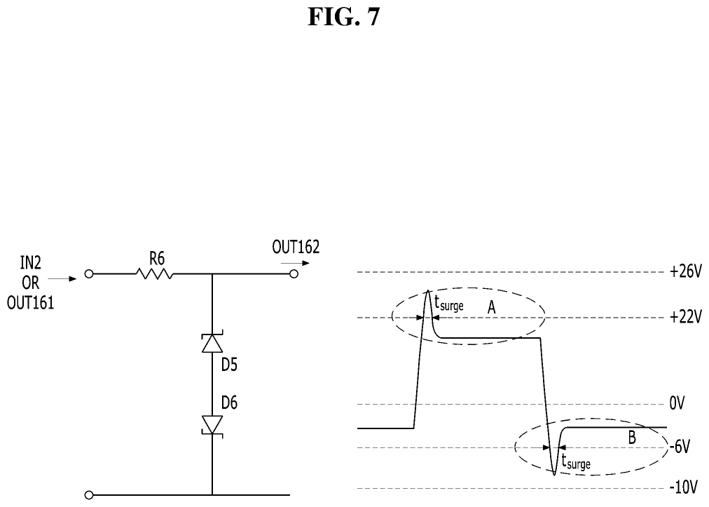

FIG. 7 is a view showing the circuit of a first negative voltage generation unit 162 according to an embodiment of the present invention.

A power semiconductor switch such as a SiC FET has a minimum Vgs value lower than those of other power switches (e.g., IGBT) and may have a value of, for example, 2V or less at 25° C. Due to this characteristic, in order to prevent malfunction of the switch of turning to on (“False On”) from an off state due to disturbance noise, the power applied to the gate as an off condition needs to be set to a negative voltage. Particularly, “False On” like this is a critical problem when vibration, charge and discharge, or back electromotive force frequently occur in an electric vehicle.

On the other hand, in the embodiment of the present invention, since the input signal IN2 is applied from the secondary side of the insulating transform unit 130, no power is separately applied for an OFF signal. Therefore, in the embodiment of the present invention, a negative voltage for preventing “False On” cannot be generated by itself.

To solve this problem, the embodiment of the present invention implements a first negative voltage generation unit 162 by connecting Zener diodes D5 and D6 to the gate and source of the power semiconductor switch 170. By this connection, a gate ON signal is applied first, and then the power semiconductor switch 170 is connected, and high voltage is charged in the capacitor connected to the load side in series. At this point, the constant voltage signal of the gate ON signal prevents VGS from being dropped by the Zener diode D6.

Thereafter, as supply of power to the primary side of the insulating transform unit 130 is blocked in an OFF state, power of the secondary side is lost. In this case, the voltage charged in the capacitor connected to the load side in series is applied to the gate through D5 and D6, and at this point, VGS forms a negative voltage corresponding to the Zener voltage of D6.

According to the configuration described above, as the first negative voltage generation unit 162 according to an embodiment of the present invention generates a negative voltage in an OFF state by using the voltage charged in capacitor connected to the load side in series without a separate power source, and may effectively prevent “False On” of the SiC power semiconductor switch.

Seeing an example of the operating range, the diode D5 maintains the voltage of VGS and controls the peak of surge voltage in region A, i.e., during the ON period. For example, when the Zener voltage of the diode D5 is 20V, the VGS voltage may be maintained between 18 and 22V.

The diode D6 determines the magnitude of the negative voltage for the VGS in region B, i.e., during the OFF period. For example, when the Zener voltage of the diode D6 is 3.8V, VGS may be maintained between −6V and 0V.

The first negative voltage described above may be provided to the power semiconductor switch 170 as a gate signal OUT162 in an OFF state.

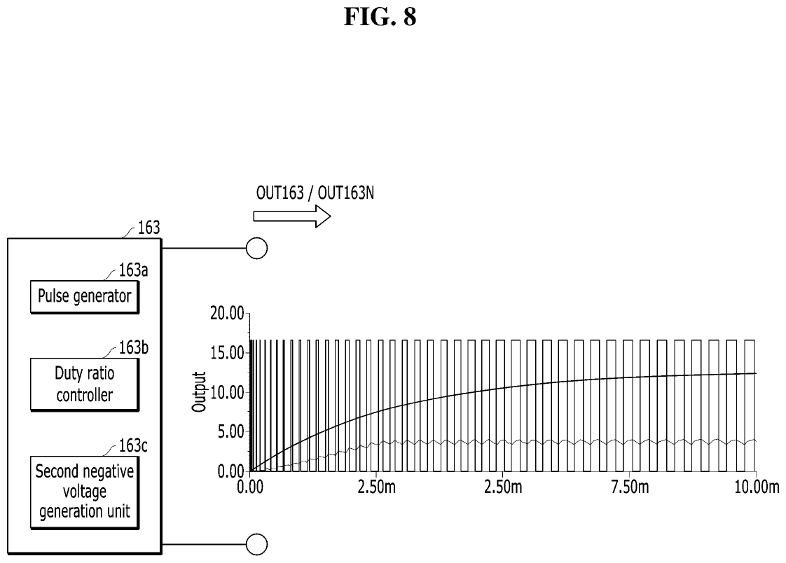

FIG. 8 is a view showing the configuration of a chopper signal generation unit 163 according to an embodiment of the present invention.

The chopper signal generation unit 163 may include a pulse generator 163a, a duty ratio controller 163b, and a second negative voltage generation unit 163c.

As described above, the series resistor 12 that reduces the in-rush current in the prior art may generate heat and energy loss. In an embodiment of the present invention, the chopper signal generation unit 163 may support soft start of the power semiconductor switch by using the chopper signal without using the series resistor.

The pulse generator 163a generates a pulse corresponding to the voltage level of IN2 by using a pulse generator such as Timer 555. In addition, the pulse generator 163a generates the pulse at a predetermined frequency to be able to operate as a gate signal.

The duty ratio controller 163b controls the duty ratio so that the generated On-duty time may increase gradually. The duty ratio controller 163b may control to gradually increase On-duty time by using a capacitor connected to the control signal input terminal of the pulse generator 163a.

The chopper signal that gradually increases On-duty time in this way is generated as gate signal OUT163 to attenuate the peak current by an equivalent resistor embedded in the load side and operate each power semiconductor switch device within each short circuit immunity range, while limiting the energy transferred to the capacitor on the load 300 side.

Therefore, according to an embodiment of the present invention, the problems generated by a large-capacity resistor, which is required when a mechanical relay is used, can be solved.

When the power semiconductor switch 170 is an IGBT, it has a short circuit immunity of about 8 us, whereas a SiC FET has a short circuit immunity of less than 3 us and a high in-rush current peak. Accordingly, when a SiC FET device is used, it is preferable to control to drive at a low voltage without using the under voltage protection unit 161.

On the other hand, when On-duty time is controlled by using the chopper signal, the SiC power semiconductor switch should generate a separate negative voltage when the switch is OFF.

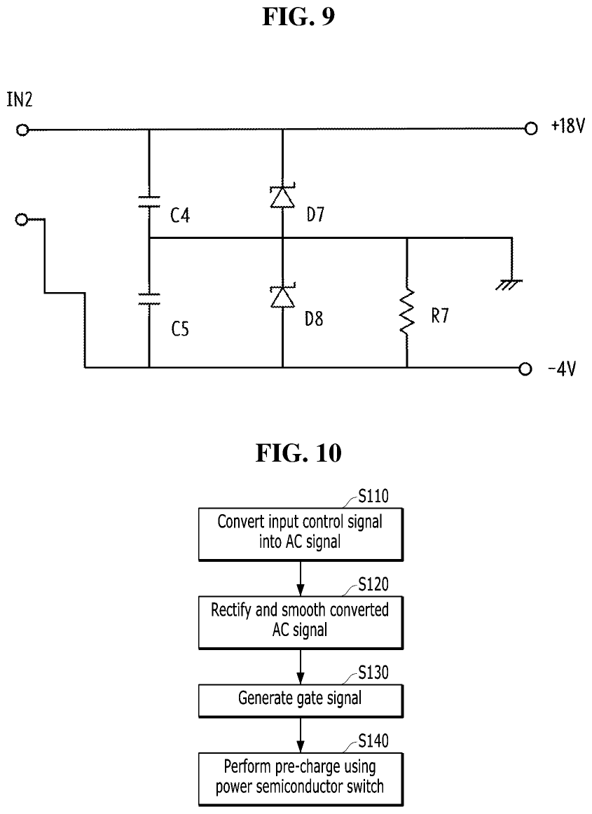

FIG. 9 is a view showing a second negative voltage generation unit according to an embodiment of the present invention.

According to the embodiment shown in FIG. 9, it is possible to separate the output IN2 of the secondary side of the insulating transform unit into a positive voltage (e.g., +18V) and a negative voltage (e.g., −4V) using the Zener diodes (D7, D8), capacitors (C4, C5), and resistor (R7), and provide the negative voltage. To this end, the second negative voltage generation unit 163c may apply the second negative voltage to the gate using the capacitor C5 capable of charging a predetermined voltage and the Zener diode D8 having a Zener voltage corresponding to the negative voltage when the power semiconductor switch 170 is turned off.

In addition, according to another embodiment of the present invention, a voltage level limited by the Zener voltage may be provided as a negative voltage using a separate power supply and the voltage charged in the Zener diode and the capacitor. Here, although a separate voltage source may be used as the charged negative voltage, when the secondary side of the insulating transform unit 130 provides a plurality of voltage taps, a tap having a potential lower than a reference potential may be connected to charge the capacitor.

When the gate signal is generated using the chopper signal in this way, the second negative voltage gate signal OUT163N may be provided to the gate of the power semiconductor switch 170.

As shown in the configuration described above, the electronic pre-charge relay device according to an embodiment of the present invention may maximize the advantages of the electronic pre-charge relay by generating an appropriate gate signal in consideration of the characteristics of each power semiconductor switch and the characteristics of an electric vehicle having severe vibration and disturbance.

FIG. 10 is a flowchart illustrating a method of driving a pre-charge relay according to an embodiment of the present invention.

At step S110, the control signal that is input to drive the pre-charge relay is converted into an AC signal. The control signal may be a single pulse or an input signal having a potential of a specific level. A control signal corresponding to turn-on is converted into an AC signal in response to input of the control signal. The converted AC control signal may include a pulse signal generated by a pulse generator. The converted AC control signal is input into the primary side of the insulating transform unit 130 and boosted to the potential of a level suitable for the gate signal of the power semiconductor toward the insulated secondary side.

At step S120, the converted and boosted AC signal is rectified, smoothed, and converted into a DC signal.

At step S130, a gate signal that can drive the power semiconductor switch is generated using the converted DC signal. The generated gate signal may include a negative signal, as well as a positive signal, and may include a chopper signal having a duty ratio that varies over time.

At step S140, pre-charging is performed by driving the power semiconductor switch using the generated gate signal. The generated gate signal is applied to the gate of the power semiconductor switch and controls on/off of the switch. The power semiconductor switch includes at least one among an IGBT and a SiC or GaN transistor that uses a wide bandgap material. The turned-on power semiconductor switch pre-charges high-voltage electrical energy into a load-side capacitor to reduce voltage difference and in-rush current.

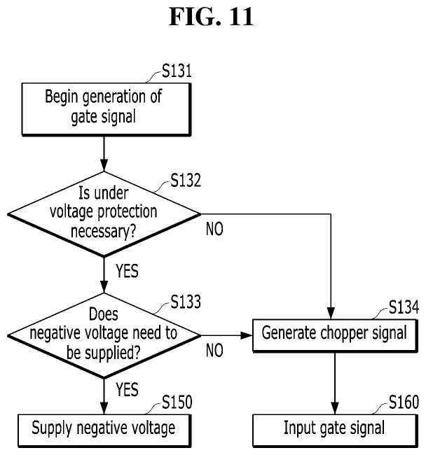

FIG. 11 is a flowchart specifically illustrating a step of generating a gate signal according to an embodiment of the present invention.

At step S131, generation of the gate signal begins on the basis of the DC signal converted at step S120.

At step S132, whether under voltage protection is required in driving the power semiconductor switch is determined. For example, whether a gate voltage needs to be applied is determined from the moment when the resulting voltage of the converted DC signal exceeds a specific voltage (e.g., 12V). It can be determined that an under voltage protection procedure described above is required to generate a gate signal of an IGBT power semiconductor switch having a minimum gate-source voltage Vgs relatively higher than that of a SiC power semiconductor.

At step S132, it is determined whether supply of a negative voltage is needed when the power semiconductor switch is turned off. For example, when a SiC power semiconductor that does not require an under voltage protection procedure is used as a power semiconductor switch, it may be determined that supply of a negative voltage is required. As it has already been described, as a power semiconductor switch such as a SiC FET has a minimum Vgs value lower than those of other power switches (e.g., IGBT), there may be a case in which the switch malfunctions in an off state due to disturbance noise and is turned on (“False On”). Therefore, in the case of a SiC power semiconductor switch, the power applied to the gate as an off condition needs to be set to a negative voltage.

When supply of a negative voltage is required, at step S150, negative voltage for preventing “false on” is supplied to the gate of the power semiconductor switch.

According to an embodiment of the present invention, it is possible to separate the output IN2 of the secondary side of the insulating transform unit into a positive voltage (e.g., +18V) and a negative voltage (e.g., −4V) using the Zener diodes (D7, D8), capacitors (C4, C5), and resistor (R7), and provide the negative voltage.

In another embodiment of the present invention, a portion of the voltage charged in the load side using the Zener voltage of the Zener diode connected between the gate and the source of the power semiconductor switch is provided as a negative voltage, without using a separate negative voltage power supply. For example, a voltage level limited by the Zener voltage may be provided as a negative voltage using the voltage charged in the Zener diode and the capacitor. Here, the voltage charged in the capacitor can be charged by connecting a tap having a potential lower than a reference potential on the secondary side of the insulating transform unit used to boost the voltage level.

At step S134, a chopper signal corresponding to the converted DC signal is generated. The DC signal includes a DC signal that has gone through an under voltage protection process.

The chopper signal may be a signal controlled to gradually increase On-duty time of the pulse generated by the pulse generator. The chopper signal that gradually increases On-duty time is supplied to the power semiconductor switch as a gate signal at step S160 to attenuate the peak current by an equivalent resistor embedded in the load side, and operate each power semiconductor switch device within each short circuit immunity range, while limiting the energy transferred to the capacitor on the load side.

All or some of the processes shown in FIG. 11 may be selected and executed according to the type of the power semiconductor switch. Selective execution of the processes may be implemented as a software module or a hardware module by the selection unit 164 shown in FIG. 5.

According to the solution described above, the embodiments of the present invention may provide a pre-charge relay device optimized for the characteristics of a power semiconductor transistor, and a driving method thereof.

In addition, the embodiments of the present invention may prevent heat generation and energy loss caused by a series resistor of a large capacity in applying an electronic pre-charge relay.

In addition, the embodiments of the present invention may be optimized for using a wide bandgap power semiconductor, such as a SiC FET, as well as an IGBT, as a pre-charge relay for electric vehicles.

It should be understood that the effects of the present invention are not limited to the effects described above, and include all effects that can be inferred from the configuration of the present invention described in the detailed description or claims of the present invention.

The description of the present invention described above is for illustrative purposes, and those skilled in the art may understand that it can be easily modified into other specific forms without changing the technical spirit or essential features of the present invention. Therefore, it should be understood that the embodiments described above are illustrative in all respects, and not restrictive. For example, each component described as a single type may be implemented in a distributed form, and components described as distributed may also be implemented in a combined form likewise.

The scope of the present invention is indicated by the claims described below, and all changes or modifications derived from the meaning and scope of the claims and their equivalent concepts should be construed as being included in the scope of the present invention.

What is claimed is:

1. An electronic pre-charge relay device comprising:
a control signal input unit for inputting a control signal for turning on and off;
an AC conversion unit for converting the control signal into an AC signal;
an insulating transform unit for boosting the converted AC control signal to a predetermined voltage level;
a rectifying and smoothing unit for converting the boosted AC control signal into a DC input signal;
a power semiconductor switch having a gate used to turn on and off to supply electrical energy to a load in relation to the control signal; and
a gate signal generation unit for generating at least one gate signal suitable for the power semiconductor switch by using the converted DC input signal.

2. The device according to claim 1, wherein the gate signal generation unit includes a chopper signal generation unit, and the chopper signal generation unit generates a pulse that gradually increases on-duty time as a gate signal on the basis of the DC input signal.

3. The device according to claim 2, wherein the chopper signal generation unit includes:
a pulse generator for generating a pulse corresponding to the DC input signal; and
a duty ratio controller for controlling to gradually increase on-duty time of the generated pulse.

4. The device according to claim 2, wherein the gate signal generation unit further includes an under voltage protection unit that determines a voltage of the DC input signal as a voltage of the gate signal only when the voltage of the DC input signal is higher than a predetermined voltage level.

5. The device according to claim 4, wherein the power semiconductor switch includes a first power semiconductor switch and a second power semiconductor switch having different minimum gate-source voltages, and the under voltage protection unit is configured to operate when a gate signal for the first power semiconductor switch having a relatively higher minimum gate-source voltage is generated.

6. The device according to claim 2, wherein the gate signal generation unit further includes a first negative voltage generation unit for generating a gate signal of a negative voltage level determined based on a Zener voltage of at least one Zener diode connected between a gate and a source of the power semiconductor switch using the voltage charged in the load when the control signal is turned off.

7. The device according to claim 6, wherein the power semiconductor switch includes a first power semiconductor switch and a second power semiconductor switch having different minimum gate-source voltages, and the first negative voltage generation unit is configured to operate when a gate signal for the second power semiconductor switch having a relatively lower minimum gate-source voltage is generated.

8. The device according to claim 3, wherein the chopper signal generation unit further includes a second negative voltage generation unit for generating a gate signal of a negative voltage level at the gate of the power semiconductor switch when the control signal is turned off, wherein the power semiconductor switch includes a first power semiconductor switch and a second power semiconductor switch having different minimum gate-source voltages, and the second negative voltage generation unit is configured to operate when a gate signal for the second power semiconductor switch having a relatively lower minimum gate-source voltage is generated.

9. The device according to claim 8, wherein the second negative voltage is provided using a tap having a potential lower than a reference potential, among a plurality of taps on a secondary side of the insulating transform unit.

10. The device according to claim 8, wherein the second negative voltage is provided by separating an output of a secondary side of the insulating transform unit into a positive voltage and a negative voltage using a plurality of Zener diodes and capacitors.

11. A method of driving an electronic pre-charge relay, the method comprising the steps of:
converting a control signal that is input to drive the electronic pre-charge relay into an AC signal, and boosting the AC signal to a predetermined voltage level;
converting the converted and boosted AC signal into a DC signal by rectifying and smoothing the AC signal;
generating a gate signal capable of driving a power semiconductor switch using the converted DC signal; and
performing pre-charge by driving the power semiconductor switch using the generated gate signal, wherein
the generated gate signal includes a chopper signal having a duty ratio that varies over time.

12. The method according to claim 11, wherein the chopper signal is a pulse that gradually increases on-duty time over time.

13. The method according to claim 12, wherein the power semiconductor switch includes a first power semiconductor switch and a second power semiconductor switch having different minimum gate-source voltages, and the step of generating a gate signal includes a step of determining that an under voltage protection is required when a gate signal for the first power semiconductor switch having a relatively higher minimum gate-source voltage is generated.

14. The method according to claim 13, wherein the step of generating a gate signal further includes a step of determining whether supply of a negative voltage for generating a gate signal of a negative voltage level to a gate of the power semiconductor switch is required when the control signal is turned off, and a step of determining that supply of the negative voltage for the second power semiconductor switch having a relatively lower minimum gate-source voltage is required.

15. The method according to claim 14, wherein the negative voltage has a voltage level determined based on a Zener voltage of at least one Zener diode connected between a gate and a source of the power semiconductor switch using a voltage charged in a load when the control signal is turned off.

16. The method according to claim 14, wherein the negative voltage is provided using a tap having a potential lower than a reference potential, among a plurality of taps on a secondary side of the insulating transform unit used when the boosting is performed.

17. The method according to claim 14, wherein the negative voltage is provided by separating an output of a secondary side of the insulating transform unit into a positive voltage and a negative voltage using a plurality of Zener diodes and capacitors.
